(19) United States
(12) Patent Application Publication
(10) Pub. No.: US 2009/0039475 A1
(43) Pub. Date: Feb. 12, 2009

(54) Apparatus and Method for Manufacturing Semiconductor

(76) Inventor: Yoshimi Shioya, Kanagawa (JP)

Correspondence Address: GLENN PATENT GROUP, 3475 EDISON WAY, SUITE L, MENLO PARK, CA, 94025, US

(21) Appl. No.: 12/089,029

(22) PCT Filed: Apr. 24, 2006
(86) PCT No.: PCT/JP2006/308544

§ 371 Date: Apr. 2, 2008

(30) Foreign Application Priority Data
Oct. 14, 2005 (JP) 2005-299971

(51) Int. Cl. H01L 23/58; G21G 5/00; C23C 16/00

(52) U.S. Cl. 257/632; 250/492.2; 118/725; 257/E21.241

(57) ABSTRACT

To provide a semiconductor manufacturing apparatus which is able to improve insulation film.

An irradiating device comprises irradiating means for irradiating light with a wavelength longer than one corresponding to the absorption edge of insulation film for said insulation film and shorter than one necessary for cutting chemical bonds, to which hydrogen of said insulation film is related.

### FIELD OF THE INVENTION

The present invention relates to an apparatus and a method for manufacturing semiconductor devices.

### BACKGROUND ART

Conventionally, a semiconductor device comprises various insulation films. These insulation films are, for example, interlayer insulation films (for example, a low dielectric constant film (referred to “Low-k film” hereinafter)), barrier insulation films of wiring material formed among wires, high dielectric constant gate insulation films (referred to “High-k film” hereinafter) and so on. In addition, SiN, SiON, SiOCH, SiOCNH, SiCH, SiCNH, SiOCF, SiCF or others are used as material for the insulation films.

Low dielectric constant and high mechanical strength are required for the Low-k film. One method to realize the low dielectric constant is thermal annealing treatment on the Low-k film. One method to realize high mechanical strength is ultraviolet light irradiation treatment, as described in Patent Document 1.

The above thermal annealing treatment requires annealing at above 400° C. for more than 30 minutes in particular. In addition, the above ultraviolet light irradiation treatment requires ultraviolet light irradiation with a wavelength shorter than 200 nm.

In addition, a barrier insulation film requires to be uniform, high-dense, and also thinner.

Furthermore, it is required that the High-k film (HfO₂ film) should be dense and its leakage current should be reduced. For this reason, annealing treatment performed after the formation of the High-k film is important. Conventionally, the High-k film is formed by metal-organic chemical vapor deposition method (MOCVD) or others. A boundary layer is formed by applying 425° C. heat while supplying O₂ gas on silicon before the formation of the High-k film, in particular. Then, the High-k film is formed by metal-organic chemical vapor deposition at 450-550° C. Then, by supplying N₂, N₂/O₂ gas or NH₃ gas at 700-900° C., Si—O bond silicon in the High-k film is nitrogenized and SiN bond is formed. Furthermore, annealing treatment is performed in argon (Ar). (Non-patent Documents 1 and 2)
Patent Document 1: JPA 2004-356508
Non-patent Document 1: IEEE Electron Devices 52, p1839 (2005)
Non-patent Document 2: The Electrochemical Society Interface, Summer 2005, p30 (2005)

### DISCLOSURE OF INVENTION

### [Problem to be Solved by the Invention]

However, when performing the conventional ultraviolet light irradiation treatment, there was a problem that mechanical strength of the Low-k film increases, though its dielectric constant also increases. For example, irradiating ultraviolet light with a wavelength of 172 nm and irradiance of 14 mW/cm² to the Low-k film with 2.4 dielectric constant for 4 minutes, Young's modulus, i.e. mechanical strength, is 8 GPa, though dielectric constant increases over 2.6.

In addition, irradiating ultraviolet light with a wavelength of 172 nm and irradiance of 14 mW/cm² to spin-on dielectric (Spin on Deposition: SOD) film, which is able to realize dielectric constant below 2.3 by performing thermal annealing treatment, for 4 minutes, Young's modulus, i.e. mechanical strength, is 8 GPa, though dielectric constant increases to 2.5.

Furthermore, due to the above annealing treatment performed at a high temperature of 400° C. for more than 30 minutes as described, for example, wiring material such as copper (Cu) used in a semiconductor device diffuses to the Low-k film and leakage current among wirings increases. In addition, the above thermal annealing treatment takes more than 30 minutes, while the other manufacturing process of a semiconductor device takes approximately 5 minutes. Therefore, the problem of performing the above thermal annealing treatment is that the manufacturing throughput of a semiconductor device decreases.

In addition, it was difficult to reduce the thickness of barrier insulation film and to increase density. Conventionally, there is no specific method for increasing the density of barrier insulation film.

Furthermore, the High-k film had a problem of containing much charges, so source/drain current will be smaller and leakage current of the High-k film will be larger. These are problems due to holes caused by loss of oxygen (O) in the High-k film.

As described above, improvements are required for each use of insulation films.

Therefore, the purpose of the present invention is to provide a semiconductor manufacturing apparatus which is able to improve insulation films.

### [Means for Solving the Problem]

To solve the above problem, the semiconductor manufacturing apparatus of the present invention comprises
irradiating means for irradiating light with a wavelength longer than one corresponding to the absorption edge of said insulation film for insulation film and shorter than one necessary for cutting chemical bonds relating to hydrogen of said insulation film,
a heater for applying heat to wafer comprising the insulation film,
a reaction chamber comprising prevention-removal means for preventing displacement of said wafer for said heater based on static electricity produced between the wafer and the heater by irradiating light from the irradiating means and
means for creating nitrogen atmosphere or inert atmosphere in the reaction chamber when irradiating light.

In particular, in case the insulation film is SiOCH film, the irradiating means will irradiate light with a wavelength of 156˜500 nm, in case the insulation film is SiOCNH film, SiCH film or SiCNH film, the irradiating means will irradiate light with a wavelength of 180˜500 nm, and in case the insulation film is SiN film, the irradiating means will irradiate light with a wavelength of 240˜500 nm.

In addition, the semiconductor manufacturing apparatus of the present invention comprises the above irradiating device and carrier device for carrying wafer comprising insulation film.

Furthermore, when manufactured by a chemical vapor deposition device, the semiconductor device of the present invention comprises insulation film with dielectric constant below 2.4 and Young's modulus above 5 GPa.

When manufactured by semiconductor device spin-coating film-forming device, the semiconductor device of the present invention provides insulation film with dielectric constant below 2.3 and Young's modulus above 6 GPa.

Furthermore, the semiconductor manufacturing method of the present invention includes
irradiating process for irradiating light with a wavelength longer than one corresponding to the absorption edge of said insulation film for insulation film and shorter than one necessary for cutting chemical bonds relating to hydrogen of said insulation film,
process for putting the insulation film in nitrogen atmosphere or inert atmosphere when irradiating light,
heating process for applying heat to wafer comprising the insulation film when irradiating light, and
process for preventing displacement of said wafer for said heater based on static electricity produced between the wafer and the heater.

### DETAILED DESCRIPTION OF THE PREFERRED EMBODIMENT

Descriptions of the embodiments of the present invention will be explained, in reference to the figures. Same parts are assigned with the same signs in each drawings.

FIG. 1 shows
a hoop 41 for containing wafer,
a wafer alignment 42 for positioning wafer removed from the hoop 41,
a load lock chamber 43 which is a decompressed chamber comprising load lock mechanism,
a first chamber 1 for irradiating light with long wavelength relative to wafer,
a second chamber 2 for irradiating light with short wavelength relative to wafer, and
a transfer chamber 44 comprising robot arm carrying wafer among the load lock chamber 43, the first chamber 1 and the second chamber 2.

FIG. 2 is a typical block diagram of the first chamber 1 in FIG. 1. FIG. 2 shows
a plurality of (for example, 4) lamps 3 for irradiating light with wavelengths of 300 nm such as high-pressure mercury lamp which is determined by material of the Low-k film,
a silica pipe 4 for protecting each lamp 3 from stress at decompressed state and preventing contact of oxygen to each lamp 3,
inert gas 5 such as nitrogen (N₂) gas supplied in silica pipe 4,
a wafer 7 which will be a semiconductor device, covered with insulator,
a heater 6 made of insulator (AIN) applying heat to the wafer 7, placed on lifting stage,
a light receiving sensor 9 mounted in silica pipe 4 or on the inner wall of the first chamber 1, for continuously, regularly and intermittently measuring irradiance of irradiating light from the lamp 3,
a piping 11 for supplying nitrogen gas in the first chamber 1,
a piping 12 for supplying oxygen (O₂) gas for cleaning inside the first chamber 1 after processing the wafer 7,
a valve 14 respectively provided between the piping 11 and 12, and
a mass flow 13 for respectively measuring gas flow passing through the piping 11 and 12 as well as controlling opening/closing of the internal valve depending on the measuring result.
   Inert gases other than nitrogen may be supplied in the first chamber 1 if necessary.

In addition, configuration of the second chamber 2 is similar to the first chamber 1, though a low-pressure mercury lamp or an excimer lamp such as Xe, Kr, I, KrBr is used instead of each lamp 3. Light with a wavelength of 186 nm is relatively intense when base part temperature of the low-pressure mercury lamp is approximately 60° C. and light with a wavelength of 254 nm is relatively intense when the base part temperature of the lamp is approximately 40° C.

Lamps for irradiating light with same wavelength may be provided on both the first chamber 1 and the second chamber 2. In this case, heating time of the wafer 7 processed by the semiconductor manufacturing apparatus shown in FIG. 1 increases 2 times longer compared to the conventional case, so improvement can be recognized in that the mechanical strength of the insulation film increases.

In addition, a visible light lamp, a xenon lamp, an argon laser or carbon dioxide gas laser can be used as the lamp 3 in the first chamber 1. Furthermore, the excimer laser such as XeF, XeCl, XeBr, KrF, KrCl, ArF or ArCl can be used as lamp in the second chamber 2. To cut the chemical bonds not in a stable state in insulation film, the lamp 3 is necessary to be one which is able to irradiate light with a wavelength shorter than 770 nm, i.e. visible light. That is to say, in case a lamp irradiating light within the wavelength range of infrared region is used as the lamp 3, most of the chemical bonds that are not in the stable state in the insulation film vibrate, though these are not cut within a limited time. It was confirmed through experiment that visible light shorter than 770 nm can preferably cut most of the C—H bond and Si—CH₃ chemical bonds and visible light shorter than 500 nm can cut even more preferably.

FIG. 3 is a diagram showing the relation between wavelength of irradiating light and bond energy of substances. The horizontal axis of FIG. 3 shows wavelength (nm) and the vertical axis shows bond energy (eV). For example, SiOCH, SiCF and others can be used for material of the Low-k film, and, SiN, SiOCH, SiON, SiOCNH, SiCNH film and others can be used for barrier film of Cu.

For example, there are C—H bond and Si—CH₃ bond in SiOCH film. Base bonds are cut when light with a wavelength a little longer than 300 nm is irradiated. Therefore, in case SiOCH film is used for insulation film, irradiating light with a wavelength shorter than 350 nm can cut the above chemical bonds.

Similar to this, there are N—H bond and Si—H bond in SiN film. Base bonds are cut when lights with wavelengths of respectively approximately 300 nm and 400 nm are irradiated. Therefore, in case SiN film is used for insulation film, irradiating light with a wavelength shorter than 400 nm can cut the above-mentioned chemical bonds.

Here, the inventor found that dielectric constant of the Low-k film can be lowered by reducing hydrogen component, fluorine component and others in an unstable bonding state in the Low-k film.

Therefore, irradiating light with a wavelength shorter than 650 nm from lamp 3 can remove C—H bond and Si—CH₃ bond from SiOCH film. Consequently, hydrogen component and others in SiOCH film are reduced and dielectric constant of SiOCH film is lowered.

In addition, the inventor found that insulation film among wirings and others can be uniform and dense by cutting chemical bonds of hydrogen component in insulation film among wirings or barrier insulation film. Furthermore, the inventor found that the High-k film can be close and passage of leakage current can be prevented by irradiating light with a wavelength shorter than that necessary for oxidation of transition metal or that necessary for cutting C—H bond to the High-k film and by UV annealing the High-k film with inert gas atmosphere including approximately 1˜2% or preferably lower than 1% of inert gas or O₂ gas.

Therefore, using lamps selecting wavelength according to the material of each of the above insulation films, insulation films can be improved to meet the requirements.

FIG. 4 is a diagram showing the relation among wavelength of irradiating light, absorption edge and bond energy. The horizontal axis of FIG. 4 shows wavelength (nm), the left vertical axis shows absorption edge (eV) and the right vertical axis shows bond energy (eV). For example, wavelength corresponding to absorption edge of SiO₂ film is 156 nm. Therefore, when light with a wavelength longer than 156 nm is irradiated to SiON film, light proceeds into the film, consequently, the light is absorbed into the configuration (skeleton of the bonds), density of SiO₂ film or SiON film increases and mechanical strength increases. Similar to this, the wavelength corresponding to the absorption edge of SiN is 275.6 nm, so when light with a wavelength longer than 275.6 nm is irradiated to SiN film, density of SiN film increases or hydrogen component and others are removed.

FIG. 5 is a typical cross-section diagram of the wafer 7 shown in FIG. 2. FIG. 5 shows
a wiring layer 31 for transmitting signal in semiconductor device,
a barrier insulation film 32 for preventing leakage of component of the wiring layer 31, which is formed on the wiring layer 31 and
the Low-k film 33 for insulating layer formed on the Low-k film itself in the following process, which is formed on the barrier insulation film 32.

Cu and others are selected as material of the wiring layer 31 whose thickness is approximately 200˜300 nm. SiOC, SiCH, SiOCH, SiOCNH and others are selected as material of the barrier insulation film 32 whose thickness is approximately 20˜30 nm. SiOCH and others are selected as material of the Low-k film 33 whose thickness is 200˜300 nm.

Then, taking the wafer 7 where SiOCH film is selected as the Low-k film 33 for an example, improvement procedure of the Low-k film 33 will be described below. In the present embodiment, first, a wafer contained in the hoop 41 is carried from a CVD device in clean room not shown in the figures. Then, wafer is removed from the hoop 41 and carried to the wafer alignment 42 side.

The wafer is positioned at the wafer alignment 42. Then, before carrying the wafer 7 to the first chamber 1, it is carried to the load lock chamber 43.

Then, pressure inside the load lock chamber 43 is reduced. When the load lock chamber 43 is reduced to the desired pressure, a gate bulb partitioning the load lock chamber 43 and the transfer chamber 44 is opened.

Then, the wafer 7 is carried in the transfer chamber 44. The wafer 7 is carried from the load lock chamber 43 to the first chamber 1 by robot arm in the transfer chamber 44.

The wafer 7 is placed on pin 8 projecting from the upper part of the heater 6 in the first chamber 1. Then, the heater 6 is lifted up and the wafer 7 placed on pin 8 is directly in contact with the heater 6. The wafer 7 is heated, for example, for approximately 90 seconds at 350˜400° C. by the heater 8 before irradiating light from lamp 3.

In addition, together with this heating, inside the first chamber 1 is exhausted by exhausting means not shown in the figures, and, the valve 14 on nitrogen gas side is opened by the mass flow 13 and nitrogen atmosphere is created in the first chamber 1. The above-mentioned heating is performed under a condition where inside the first chamber 1 is, for example, 1 Torr and opening/closing control of the valve 14 is performed under a condition that nitrogen gas supplied to the first chamber 1 is, for example, 100 cc/min.

Inside the first chamber 1 may be at a normal pressure, not a reduced pressure. In addition, if necessary, other inert gases may be supplied in the first chamber 1 instead of N₂ gas or mixed gas of N₂ gas and other inert gases may be used.

The heater 8 is lifted to the position that the distance between the wafer 7 and the lamp 3 will be, for example, within 100˜200 mm, so that light irradiating from the lamp 3 reaches the wafer 7 with even intensity.

Then, light is irradiated from the lamp 3 to the wafer 7. In this case, irradiation of light is measured by the light receiving sensor 9 and lamp is controlled so that the irradiance is 8 mW/cm² using high-pressure mercury lamp and 15 mW/cm² using halogen lamp, for example.

In this case, when light with the above irradiation is irradiated to the wafer 7, crack of insulation film in the wafer 7 or separation of said insulation film may appear due to desorption gas. Based on measurements of the light receiving sensor 9, irradiation of the lamp 3 is increased continuously or stepwise in 5˜10 seconds. Irradiation may be increased, for example, in linear, exponential or other shape.

Then, after a predetermined time (for example, 1˜2 minutes) has passed after the start of irradiation, irradiation is finished and the valve 14 on nitrogen gas side is closed. In this way, unstable C—H bond, Si—CH₃ bond, H—CH₂Si(CH₃)₃ bond and others in the barrier insulation film 32 and the Low-k film 33 are removed and dielectric constant of the Low-k film 33 is lowered.

For example, keeping decompressed state of 1 Torr, the valve 14 on oxygen gas side is opened and the first chamber 1 is cleaned by supplying O₂ gas into the first chamber 1 for approximately 1 minute at the rate of 100 cc/min.

Then, the wafer 7 is carried from the first chamber 1 to the second chamber 2 by the transfer chamber 44. The wafer 7 is processed in the second chamber 2 just as same as the processing in the first chamber 1, though the irradiation of the light from low-pressure mercury lamp to the wafer 7 is set to 3 mW/cm². In addition, irradiating time is, for example, 1˜4 minutes. By this irradiation, increase of dielectric constant of the Low-k film can be prevented and mechanical strength can be increased.

Wafer removed from the second chamber 2 has, for example, the Low-k film 33 with Young's modulus over approximately 5 GPa and dielectric constant below 2.5. In addition, the barrier insulation film 32 has Young's modulus of approximately 60 GPa, dielectric constant of approximately 4.0 and density of approximately 2.5 g/cm³.

### EMBODIMENT 2

FIG. 6 is a typical block diagram of semiconductor manufacturing apparatus in embodiment 2 of the present invention. The present embodiment realizes one chamber 15 as a substitute for the first chamber 1 and the second chamber 2 shown in FIG. 1.

Chamber 15 comprises a plurality of (for example, 5) the lamp 3 and a plurality of (for example, 4) lamp 21. Here, the distance between lamp 21 and the wafer 7 is approximately 100 mm when using chamber 15. The distance between the lamp 3 and the wafer 7 is approximately 120 mm. The numbers of the lamp 3 and low-pressure mercury lamp 21 may be the same and the lamp 3 and lamp 21 may be placed two-dimensionally.

Ultraviolet light may be irradiated to the wafer 7 first from the lamp 3 or lamp 21. However, irradiating ultraviolet light by those lamps at the same time, dielectric constant of the Low-k film cannot be lowered and the mechanical strength cannot be increased.

Manufacturing process of semiconductor device is same as embodiment 1. Each irradiating time of the lamp 3 and lamp 21 may be set as same as embodiment 1. Under this condition, heating time of the wafer 7 before irradiation is 1 minute, total irradiating time is 5 minutes and cleaning time is 1 minute, so if the time for other processes is also 7 minutes, the manufacturing throughput will not be decreased.

### EMBODIMENT 3

Processing of the Low-k film 33 was described mainly in embodiments 1 and 2. Processing for increasing stress of SiN film of strained silicon device is explained in the present embodiment.

Strained silicon technology is used as a technology using insulation film in semiconductor devices. Strained silicon technology is a technology for increasing electron density by providing silicon germanium (SiGe) layer at source/drain, expanding the space of silicon atom taking advantage of the aligning property of lattice of silicon atom in channel region under the gate, reducing the number of collisions of electron and silicon atom which are leaders of source/drain current and increasing mobility of electron.

By this technology, resistance when electron is passing is lowered, so high-speed mobility of electron can be realized. Therefore, when strained silicon technology is used for transistor, transistor which is able to operate in high-speed can be realized. To use strained silicon technology for transistor, a method, for example, for forming SiN film on N channel transistor, irradiating thermal annealing or halogen light and straining silicon substrate is adopted.

Semiconductor manufacturing apparatus shown in FIG. 1 or FIG. 6 can also be used in the present embodiment. However, for example, I₂ lamp irradiating light with a wavelength of 341 nm is used as substitute for lamp 3, and, for example, XeBr lamp irradiating light with a wavelength of 282 nm or XeCl lamp irradiating light with a wavelength of 308 nm is used as substitute for lamp 21.

In the present embodiment, hydrogen is desorbed from SiN film by irradiating light from 12 lamp and stress of SiN film is increased by irradiating light from XeBr lamp.

FIG. 8 is a typical cross section diagram of a part of the wafer 7 shown in FIG. 2. FIG. 8 shows
P-type silicon layer 51,
N-type well region 52 provided in P-type silicon layer 51,
source region 53 and drain region 54 such as SiGe formed in N-type well region 52,
gate insulation film 62 formed on N-type well region 52,
gate electrode 55 formed on gate insulation film 62,
source region 58 and drain region 59 such as SiGe formed on P-type silicon layer 51,
gate electrode 60 formed on gate insulation film 63,
SiO₂ films 56 and 61 formed on gate electrode 55 and 60 and
SiN film 57 which is a sidewall formed on SiO₂ films 56 and 61.

Transistor on source region 53 and drain region 54 side is P channel transistor and transistor on source region 58 side and drain region 59 side is N channel transistor. This wafer 7 is formed by diffusion furnace, ion implantation equipment and chemical vapor deposition (CVD) device.

Approximately 70% of hydrogen component and others in SiN film 57 is reduced by irradiating light from the above 12 lamp, the remaining hydrogen in SiN film 57 is removed by XeBr lamp and hydrogen in SiN film 57 is almost completely eliminated. Mechanical strength of SiN film 57 is increased in this way.

FIG. 9 is a typical cross section diagram after a part of SiN film 57 of the wafer 7 shown in FIG. 8 is removed. After the above light irradiation treatment, P channel transistor side of SiN film 57 is removed. In this way, strained silicon device is created.

When the processing is performed using semiconductor manufacturing apparatus under the same condition as the present embodiment, hydrogen concentration of SiN cover insulation film can be lowered, gate/drain leakage current due to hydrogen in cover film of DRAM can be lowered and defective retention can be reduced.

### EMBODIMENT 4

FIG. 10 is a typical block diagram of the first chamber 1 in embodiment 4 of the present invention. This the first chamber 1 is preferred when halogen lamp with a wavelength longer than 400 nm is used.

As shown in FIG. 10, in the present embodiment, cooling water 22 is used to cool halogen lamp 3. Here, the light of halogen the lamp 3 applies heat to the insulation film on Si wafer and removes hydrogen in a short time.

Then, UV light is irradiated from XeCl lamp with 308 nm in the second chamber 2 and stress is increased.

### EMBODIMENT 5

FIG. 11 is a typical block diagram of the semiconductor manufacturing apparatus in embodiment 5 of the present invention.

First, in chamber 101 providing coater for spin-coating SOD film, for example, 500 nm of SOD film is coated on a wiring formed in a wafer with thickness of 300 nm.

Then, this wafer is moved to chamber 102 providing bake stage for extracting solvent of SOD film and solvent is extracted by baking at approximately 200° C.

Then, this wafer is moved to chamber 103 providing cure stage for extracting solvent and porogen or strengthening the film and baked at approximately 400° C. for 5 minutes. In this way, by extracting solvent or porogen in SOD film, the film becomes dense. Then, the same processing as embodiment 1 is performed. In this case, the Low-k film has a dielectric constant below 2.3 and Young's modulus above 6 GPa.

### EMBODIMENT 6

FIG. 12 is a typical cross section diagram of a part of the wafer 7 which is a semiconductor device in embodiment 6 of the present invention. Here, an example of UV annealing the High-k film 73 in the wafer 7 is described.

For example, boundary layer 72 of SiO₂ rich with thickness of 1 nm is formed on silicon wafer 71. On boundary layer 72, the High-k film 73 made of HfO₂ and others is formed with thickness of, for example, 5 nm. Electrode 74 made of polysilicon and others is formed on the High-k film 73. the High-k film 73 is formed by, for example, supplying N₂ gas/O₂ gas for approximately 10 minutes at 800° C.

In the first chamber 1, light is irradiated from XeCl lamp 4 which is 100˜200 mm kept away from wafer at an irradiation of approximately 5˜15 mW/cm² for approximately 2˜4 minutes.

Then, in the second chamber 2, light is irradiated from Xe lamp 4 which is 100˜200 mm kept away from wafer at an irradiation of approximately 4˜8 mW/cm² for approximately 1˜3 minutes.

The first chamber 1 and the second chamber 2 are inert gas atmosphere with decompressed state of approximately 1 Torr and temperature of approximately 500° C.

Furthermore, cleaning is performed by supplying oxygen gas at the rate of, for example, 100 cc/minute and lighting the UV lamp under decompressed state of approximately 1 Torr.

Accordingly, charge density in boundary layer 72 can be reduced to 1×10¹²/cm³ and leakage current of HfO₂ film can be lowered.

### EMBODIMENT 7

So far, semiconductor manufacturing apparatus and others using lamp irradiating light with 2 kinds of wavelength were described in each of the above embodiments, though it is able to improve the insulation film by specifying the wavelength of the lamp as described using FIGS. 3 and 4.

In case of SiN film, there are chemical bonds related to hydrogen such as H—N and H—Si. Necessary wavelengths to break these chemical bonds are respectively 353 nm and 399 nm. In addition, wavelength of approximately 240 nm corresponds to the absorption edge. From these matters, when irradiating light with a wavelength of 180-400 nm to SiN film, mechanical strength of insulation film can be increased and dielectric constant can be lowered.

In case of SiCH film, there are chemical bonds related to hydrogen such as H—N, C—H and H—Si. Necessary wavelengths to break these chemical bonds are respectively 353 nm, 353 nm and 399 nm. In addition, wavelength of approximately 265 nm corresponds to the absorption edge. From these matters, when irradiating light with a wavelength of 180-400 nm to SiCH film, mechanical strength of insulation film can be increased and dielectric constant can be lowered.

In case of SiCNH film, there are chemical bonds related to hydrogen such as H—N, C—H and H—Si. Necessary wavelengths to break these chemical bonds are respectively 274 nm, 353 nm, 353 nm and 399 nm. In addition, wavelength of approximately 265 nm corresponds to the absorption edge. From these matters, when irradiating light with a wavelength of 274-400 nm to SiCNH film, mechanical strength of insulation film can be increased and dielectric constant can be lowered.

In case of SiOCNH film, there are chemical bonds related to hydrogen such as H—O, H—N, C—H and H—Si. Necessary wavelengths to break these chemical bonds are respectively 280 nm, 353 nm, 353 nm and 399 nm. In addition, wavelength of approximately 156-263 nm corresponds to the absorption edge, though considering that concentration of C and N are above a certain percent, it can be considered that wavelength of approximately 180 nm corresponds to the absorption edge. Therefore, when irradiating light with a wavelength of 180-400 nm to SiOCNH film, mechanical strength of insulation film can be increased and dielectric constant can be lowered.

In case of SiOCH film, there are chemical bonds related to hydrogen such as H—O, H—N, C—H and H—Si. Necessary wavelengths to break these chemical bonds are respectively 280 nm, 353 nm, 353 nm and 399 nm. In addition, wavelength of approximately 156 nm corresponds to the absorption edge. From these matters, when irradiating light with a wavelength of 156-400 nm to SiOCH film, mechanical strength of insulation film can be increased and dielectric constant can be lowered.

In case of SiON film, there are chemical bonds related to hydrogen such as H—O, N—H and H—Si. Necessary wavelengths to break these chemical bonds are respectively 280 nm, 353 nm and 399 nm. In addition, wavelength of approximately 263 nm corresponds to the absorption edge. From these matters, when irradiating light with a wavelength of 263-400 nm to SiON film, mechanical strength of insulation film can be increased and dielectric constant can be lowered.

### EMBODIMENT 8

FIG. 17 is a typical block diagram of prevention ring 8A for preventing displacement of the wafer 7 set in the first chamber 1 and the second chamber 2. The wafer 7 and the heater 6 already described is shown in FIG. 17.

The first chamber 1 and the second chamber 2 relating to embodiment 8 of the present invention prevent displacement by static electricity. Electricity removing ring may be used instead of prevention ring 8A to remove static electricity. Prevention ring 8A is used surrounding the wafer 7 on the heater 6.

Here, when ultraviolet light and others are irradiated from the lamp 3 to the wafer 7, negative/positive charge, i.e. static electricity is generated between the wafer 7 and the heater 6. Accordingly, the wafer 7 and the heater 6 will attract each other. Here, when lifting stage is moved down to keep the wafer 7 away from the heater 6 after a predetermined processing, the wafer 7 might be displaced from the heater 6 by said static electricity.

Generally, a sensor for detecting this displacement is provided in a chamber. Therefore, when the above displacement exceeds a predetermined amount, this sensor responds and the manufacturing process stops. It will be unable to perform continuous processing and manufacturing throughput decreases.

Consequently, prevention ring 8A for preventing the above sensor from responding to displacement of the wafer 7 is set in the first chamber 1 and the second chamber 2 as described above and the wafer 7 can be stopped at the inner wall of prevention ring 8A. In case of electricity removing ring 8A, its surface should be at least polysilicon, monocrystalline silicon or aluminum.

Electricity removing ring 8A is not limited to the shape shown in FIG. 17, but may have the shape of, for example, rectangular solid, cube or others. This kind of electricity removing object may be placed on the heater 6 where it does not disturb carrying in/out the wafer 7. However, for example, as shown in FIG. 18, the wafer 7 is easily carried in to the position surrounded by a plurality of electricity removing ring piece 8B in approximate rainbow shape, so the wafer 7 is less displaceable. Either of electricity removing objects shaped in rectangular solid and others or electricity removing ring piece 8B are easily created compared to electricity removing ring 8A.

Furthermore, if generated static electricity can be removed, it is not necessary to provide electricity removing ring 8A or others. For example, as substitute for providing electricity removing ring 8A and others or with these, electricity removing pin can be used instead of pin 8. Surface of electricity removing pin may be polysilicon, monocrystalline silicon, aluminum or others.

In the same way, polysilicon thin film, amorphous silicon thin film, SiN thin film, SiC film or SiOC film can be formed on the surface of the heater 6 and others. Thickness of thin film is not limited, though it may be 500˜10000 angstrom, for example.

For example, polysilicon thin film with thickness of approximately 5000˜10000 angstrom can be formed by applying 380 KHz of high-frequency 562 W to the heater 6 by plasma CVD method, sputter method or low-pressure CVD method and applying SiH₄ at 100 cc/min under a condition of 350° C. substrate surface temperature and 0.6 Torr pressure. SiN thin film with thickness of approximately 3000—5000 angstrom can be formed by applying 380 KHz of high-frequency 562 W to the heater 6 by plasma CVD method, sputter method or low-pressure CVD method and applying SiH₄ at 100 cc/min and NH3 at 500 cc/min under a condition of 350° C. substrate surface temperature and 0.6 Torr pressure.

In case SiN thin film is formed on the surface of the heater 6 and others, current will be easier to pass by using silicon-rich type, which is preferred because the wafer 7 is less adsorbable to the heater 6. Particularly, in case SiC film or SiOC film is formed on the surface of the heater 6 or others, a secondary effect preventing contamination of the wafer 7 can be obtained by aluminum component and others of the heater 6 or electricity removing ring 8A.

### EMBODIMENT 9

FIG. 19˜21 is a diagram showing deformation example of the manufacturing process of the wafer 7 shown in FIGS. 8 and 9. Means where P channel transistor is compressive film and N channel transistor is tensile film is described here.

In the present embodiment, first, a polysilicon thin film 64 with thickness of approximately 100 nm which is ultraviolet light absorber is formed on transistor on the source region 53 and drain region 54 side of the wafer 7, i.e. P channel transistor. Under this condition, low-pressure mercury UV light with irradiation of 14 mW/cm2 is irradiated to P channel transistor and N channel transistor at 400° C. for 5 minutes. (FIG. 19)

In this way, SiN film 57 on N channel transistor side will be approximately 1.5 GPa of tensile stress. Ultraviolet light absorber is not limited to polysilicon, if it comprises a bandgap for realizing said absorption and if it is tolerant of applying heat of approximately 400° C.

Following this, the polysilicon thin film 64 formed on a P channel transistor is removed (FIG. 20). In this way, SiN film 57 on N channel transistor side becomes the only tensile stress.

Then, the N channel transistor is covered with thick resist film 65 and, for example, N⁺ ion is implanted into the center of SiN film 57 on the P channel transistor side at 5×10¹⁵ dose using ion implanter (FIG. 21). Here, SiN film 57 on N channel transistor side is protected by resist film 65, so stress does not change. At the same time, stress of SiN film 57 on P channel transistor side becomes compressive, which is approximately 1 GPa.

Then, by removing resist film 65 covering N channel transistor, the wafer 7 shown in FIG. 8 is completed.

### WORKING EXAMPLE

### Working Example 1

The semiconductor device was actually manufactured through processing of the Low-k film 33 under the following conditions using semiconductor manufacturing apparatus shown in FIG. 1, FIG. 17 or other figures.

the lamp 3 of the first chamber 1: 4 high-pressure mercury lamps with approximately 300 nm to 770 nm wavelengths, irradiation of approximately 8 mW/cm² for approximately 4 minutes

low-pressure mercury lamp of first chamber 2: 4 lamps with approximately 186 nm and approximately 254 nm wavelengths, irradiation of approximately 3 mW/cm² for approximately 1 minute

the first chamber 1 and the second chamber 2: decompressed state of 1 Torr, approximately 400° C., various inert gas atmosphere including nitrogen gas, cleaning condition with oxygen gas supply of 100 cc/min. under 1 Torr decompressed state

the wafer 7: SiOCH film with a diameter of approximately 300 mm and thickness of approximately 300 nm is formed.

This resulted in Young's modulus, showing mechanical strength of the wafer 7, of 8 GPa.

### Working Example 2

The semiconductor device was actually manufactured through processing of the Low-k film 33 under the following conditions using semiconductor manufacturing apparatus shown in FIG. 6, FIG. 17 or other figures.

lamp 3: 4 high-pressure mercury lamps with approximately 300 nm to 770 nm wavelengths, irradiation of approximately 4 mW/cm² for approximately 4 minutes

lamp 21: 4 low-pressure mercury lamps with approximately 186 nm and approximately 254 nm wavelengths, irradiation of approximately 3 mW/cm² for approximately 1 minute

chamber: decompressed state of 1 Torr, approximately 250° C., various inert gas atmosphere including nitrogen gas, cleaning condition with oxygen gas supply of 100 cc/min. under 1 Torr decompressed state

the wafer 7: SiOCH film with a diameter of approximately 300 mm and thickness of approximately 300 nm is formed.

This resulted in Young's modulus, showing mechanical strength of the wafer 7, of 8 GPa. Dielectric constant resulted in 2.4.

### Working Example 3

The semiconductor device was actually manufactured through processing of SiN film 57 under the following conditions using the semiconductor manufacturing apparatus shown in FIG. 1, FIG. 17 or other figures.

the lamp 3 in the first chamber 1: 4 I₂ lamps with approximately 341 nm wavelengths, irradiation of approximately 13 mW/cm² for approximately 2 minutes

lamp in the second chamber 2: 4 XeBr lamps with approximately 282 nm wavelengths, irradiation of approximately 13 mW/cm² for approximately 2 minutes

the first chamber 1: decompressed state of 1 Torr, approximately 400° C., various inert gas atmosphere including nitrogen gas, cleaning condition with oxygen gas supply of 100 cc/min. under 1 Torr decompressed state

the second chamber 2: decompressed state of 1 Torr, approximately 400° C., various inert gas atmosphere including nitrogen gas, cleaning condition with oxygen gas supply of 100 cc/min. under 1 Torr decompressed state

the wafer 7: a diameter of approximately 300 mm, DRAM is formed, cover SiN film with thickness of approximately 300 nm is formed on cover SiO₂ film

Accordingly, hydrogen concentration of cover SiN film 57 can be lowered, gate/drain leakage current of DRAM can be lowered, data retention time can be extended and defective rate can be lowered.

### Working Example 4

The semiconductor device was actually manufactured through processing of SiN film 57 under the following conditions using semiconductor manufacturing apparatus shown in FIG. 1, FIG. 17 or other figures.

the lamp 3 in the first chamber 1: 4 I₂ lamps with approximately 341 nm wavelengths, irradiation of approximately 13 mW/cm² for approximately 2 minutes

lamp in the second chamber 2: 4 XeCl lamps with approximately 308 nm wavelengths, irradiation of approximately 13 mW/cm² for approximately 2 minutes

the first chamber 1: decompressed state of 1 Torr, approximately 250° C., various inert gas atmosphere including nitrogen gas, cleaning condition with oxygen gas supply of 100 cc/min under 1 Torr decompressed state

the second chamber 2: decompressed state of 1 Torr, approximately 350° C., various inert gas atmosphere including nitrogen gas, cleaning condition with oxygen gas supply of 100 cc/min under 1 Torr decompressed state

the wafer 7: a diameter of approximately 300 mm, DRAM is formed, sidewall SiN film with thickness of approximately 300 nm is formed on transistor

Measuring the mechanical strength before and after processing of semiconductor manufacturing apparatus, tensile stress was 2×10⁹ dyne/cm² before processing and 2×10¹⁰ dyne/cm² after processing. Accordingly, source/drain current increased.

### Working Example 5

The semiconductor device was actually manufactured through processing of the Low-k film 33 under the following conditions using semiconductor manufacturing apparatus shown in FIG. 1, FIG. 17 or other figures.

halogen lamp in the first chamber 1: 4 lamps with approximately 400 nm to 770 nm wavelengths, irradiation of approximately 15 mW/cm² for approximately 2 minutes

low-pressure mercury lamp in the second chamber 2: 4 lamps with approximately 186 nm and approximately 254 nm wavelengths, irradiation of approximately 3 mW/cm² for approximately 2 minutes

the first chamber 1 and the second chamber 2: decompressed state of 1 Torr, approximately 400° C., various inert gas atmosphere including nitrogen gas, cleaning condition with oxygen gas supply of 100 cc/min. under 1 Torr decompressed state

the wafer 7: a diameter of approximately 300 mm, SiOCH film with thickness of approximately 300 nm is formed

This resulted in Young's modulus, showing mechanical strength of the wafer 7, of 8 GPa. Dielectric constant resulted in 2.4.

### Working Example 6

The semiconductor device was actually manufactured through processing of SOD film 33 under the following conditions using semiconductor manufacturing apparatus shown in FIG. 1, FIG. 17 or other figures.

the lamp 3 in the first chamber 1: 4 XeCl lamps with approximately 308 nm wavelengths, irradiation of approximately 10 mW/cm² for approximately 4 minutes

lamp in the second chamber 2: 4 Xe lamps with approximately 172 nm wavelengths, irradiation of approximately 4 mW/cm² for approximately 1 minute

the first chamber 1 and the second chamber 2: decompressed state of 1 Torr, approximately 350° C., various inert gas atmosphere including nitrogen gas, cleaning condition with oxygen gas supply of 100 cc/min. under 1 Torr decompressed state

the wafer 7: a diameter of approximately 300 mm, SOD film 33 with thickness of approximately 300 nm is formed

This resulted in Young's modulus, showing mechanical strength of the wafer 7, of 8 GPa. Dielectric constant resulted in 2.3.

### Working Example 7

The semiconductor device was actually manufactured through processing of HfO₂ film 33 under the following conditions using semiconductor manufacturing apparatus shown in FIG. 1, FIG. 17 or other figures.

the lamp 3 in the first chamber 1: 4 XeCl lamps with approximately 308 nm wavelengths, irradiation of approximately 10 mW/cm² for approximately 4 minutes

lamp in the second chamber 2: 4 Xe lamps with approximately 172 nm wavelengths, irradiation of approximately 4 mW/cm² for approximately 1 minute

the first chamber 1 and the second chamber 2: decompressed state of 1 Torr, approximately 500° C., various inert gas atmosphere including nitrogen gas, cleaning condition with oxygen gas supply of 100 cc/min. under 1 Torr decompressed state

the wafer 7: a diameter of approximately 300 mm, boundary layer of SiO₂ rich with thickness of approximately 1 nm and HfO₂ film with thickness of approximately 5 nm formed on boundary layer is formed

Accordingly, charge density in boundary layer can be decreased to 1×10¹²/cm³ and leakage current of HfO₂ film can be lowered.

### Working Example 8

The semiconductor device was actually manufactured using semiconductor manufacturing apparatus shown in FIG. 6, FIG. 17 or other figures. The present embodiment describes an example of increasing density of barrier insulation film (SiOC film) 22 formed on Cu wiring layer 21 shown in FIG. 13.

lamp: 4 KrCL₂ lamps with approximately 222 nm wavelengths, irradiation of approximately 4˜15 mW/cm² for approximately 1˜2 minutes, distance to the wafer 7 is approximately 10˜20 cm

chamber: decompressed state of 1 Torr, approximately 300˜400° C., various inert gas atmosphere including nitrogen gas, cleaning condition with oxygen gas supply of 100 cc/min. under 1 Torr decompressed state

the wafer 7: a diameter of approximately 300 mm and, as shown in FIG. 13, SiOC film 22, barrier film with thickness of approximately 30 nm, is formed on Cu wiring layer 21

When SiOC film 22 improved in this way was heat treated at approximately 400° C. for 3 hours, hardly any leakage current passed from SiOC film 22 due to its high-density.

### Working Example 9

The semiconductor device was actually manufactured using the semiconductor manufacturing apparatus shown in FIG. 6, FIG. 17 or other figures. The present embodiment describes an example of increasing density of PE-CVDSiN film 24 deposited on a window which was opened on barrier insulation film 23, which was formed on Cu wiring layer 21 shown in FIG. 14 through the Low-k film (SiOC film) 22.

lamp: 4 XeCL lamps with approximately 308 nm wavelengths, irradiation of approximately 4˜15 mW/cm² for approximately 1˜2 minutes, distance to the wafer 7 is approximately 10˜20 cm

chamber: decompressed state of 1 Torr, approximately 300˜400° C., various inert gas atmosphere including nitrogen gas, cleaning condition with oxygen gas supply of 100 cc/min. under 1 Torr decompressed state

the wafer 7: a diameter of approximately 300 mm, as shown in FIG. 14, Cu wiring layer 21, SiOC film 22 which is the Low-k film with thickness of approximately 30 nm, barrier insulation film 23 and PE-CVDSiN film 24 are formed from the substrate side

When tantalum/tantalum nitride (Ta/TaN) which are nonproliferation metal 25 and 26 are formed for PE-CVDSiN film 24 improved in this way as shown in FIG. 15 and when the wafer 7 which formed Cu wiring layer 27 in via is heat treated at approximately 400° C. for 3 hours, Ta in nonproliferation (barrier) metal 25 and 26 did not proliferate for SiOC film 22 due to high-density of PE-CVDSiN 24 forming side of via hole.

### Working Example 10

By the way, in case of DRAM comprising Shallow Trench Isolation (STI) area, when negative bias is applied to a word line, leakage current between gate/drain increases, so retention failure of data occurs. In addition, these are known to occur when package processing is performed at 250° C.

Cause of these phenomena is due to hydrogen in cover SiN film. This hydrogen is considered to generate trap in forbidden band of channel area where gate and drain overlaps.

In the present embodiment, the semiconductor device was actually manufactured using semiconductor manufacturing apparatus shown in FIG. 6, FIG. 17 or other figures. An example of increasing density of cover PE-CVDSiN film 84 covering cover SiO₂ film 83 formed on transistor 82 formed on silicon wafer 81 shown in FIG. 16 is described here.

lamp: 4 XeCL lamps with approximately 308 nm wavelengths, irradiation of approximately 4˜15 mW/cm² for approximately 1˜2 minutes, distance to the wafer 7 is approximately 10˜20 cm

chamber: decompressed state of 1 Torr, approximately 300˜400° C., various inert gas atmosphere including nitrogen gas, cleaning condition with oxygen gas supply of 100 cc/min under 1 Torr decompressed state

the wafer 7: a diameter of approximately 300 mm, as shown in FIG. 15, transistor 82 and others are formed.

Measuring hydrogen concentration of cover PE-CVDSiN film 84 improved in this way shows that the hydrogen concentration was approximately 30% before improvement and approximately 10% after improvement. When substituting cover LP-CVDSiN film by changing pressure in CVD process of cover PE-CVDSiN film 84, it was approximately 25% before improvement and approximately 1% after improvement.

### Working Example 11

Modified example of working example 4 will be described herein. The semiconductor device was actually manufactured through processing of HfO₂ film 33 under the following conditions using the semiconductor manufacturing apparatus shown in FIG. 6, FIG. 17 or other figures.

lamp: four XeBr lamps with approximately 282 nm wavelengths, irradiation of approximately 5˜13 mW/cm² for approximately 3 minutes

chamber: decompressed state of 1 Torr, approximately 250° C., various inert gas atmosphere including nitrogen gas, cleaning condition with oxygen gas supply of 100 cc/min. under 1 Torr decompressed state

the wafer 7: a diameter of approximately 300 mm, LP-SiN film which is sidewall is formed with thickness of approximately 300 nm

Measuring the mechanical strength before and after processing of the semiconductor manufacturing apparatus, as in embodiment 4, tensile stress was 2×10⁹ dyne/cm² before processing and 2×10¹⁰ dyne/cm² after processing. Accordingly, source/drain current increased.

### BRIEF DESCRIPTION OF THE DRAWINGS

FIG. 1 is a typical block diagram of semiconductor manufacturing apparatus in embodiment 1 of the present invention.

FIG. 2 is a typical diagram of the first chamber 1 in FIG. 1.

FIG. 3 is a diagram showing relation between wavelength of irradiating light and bond energy of substances.

FIG. 4 is a diagram showing relation between wavelength of irradiating light, absorption edge and bond energy.

FIG. 5 is a typical cross-section diagram of the wafer 7 shown in FIG. 2.

FIG. 6 is a typical block diagram of semiconductor manufacturing apparatus in embodiment 2 of the present invention.

FIG. 7 is a typical block diagram of chamber 15 in FIG. 6.

FIG. 8 is a typical cross section diagram of a part of the wafer 7 shown in FIG. 2.

FIG. 9 is a typical cross section diagram after a part of SiN film 57 of the wafer 7 shown in FIG. 8 is removed.

FIG. 10 is a typical block diagram of the first chamber 1 in embodiment 4 of the present invention.

FIG. 11 is a typical block diagram of semiconductor manufacturing apparatus in embodiment 5 of the present invention.

FIG. 12 is a typical cross section diagram of a part of the wafer 7 which is semiconductor device in embodiment 6 of the present invention.

FIG. 13 is a cross section diagram of a part of semiconductor manufacturing apparatus in embodiment of the present invention.

FIG. 14 is a cross section diagram of a part of semiconductor manufacturing apparatus in embodiment of the present invention.

FIG. 15 is a cross section diagram of a part of semiconductor manufacturing apparatus in embodiment of the present invention.

FIG. 16 is a cross section diagram of a part of semiconductor manufacturing apparatus in embodiment of the present invention.

FIG. 17 is a typical block diagram of prevention ring 8A for preventing displacement of the wafer 7 provided in the first chamber 1 and the second chamber 2.

FIG. 18 is a diagram showing a deformation example of FIG. 17.

FIG. 19 is a diagram showing a deformation example of manufacturing process of the wafer 7 shown in FIG. 8 and FIG. 9.

FIG. 20 is a diagram showing a deformation example of manufacturing process of the wafer 7 shown in FIG. 8 and FIG. 9.

FIG. 21 is a diagram showing a deformation example of manufacturing process of the wafer 7 shown in FIG. 8 and FIG. 9.

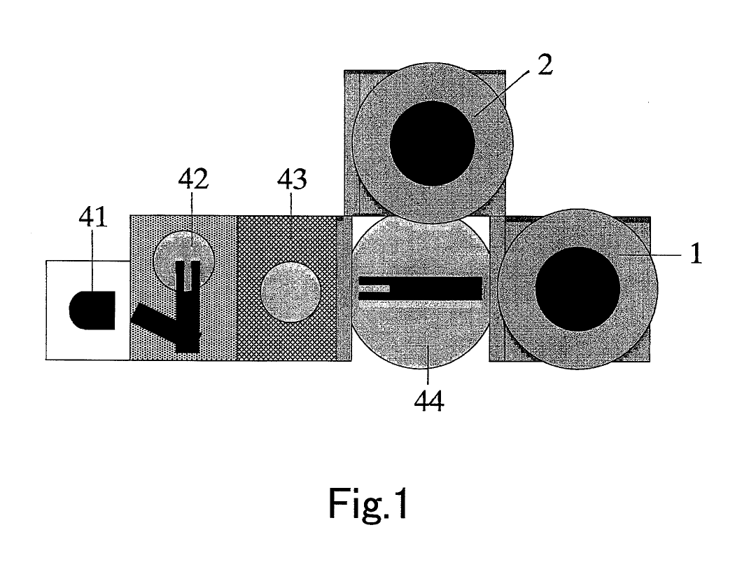

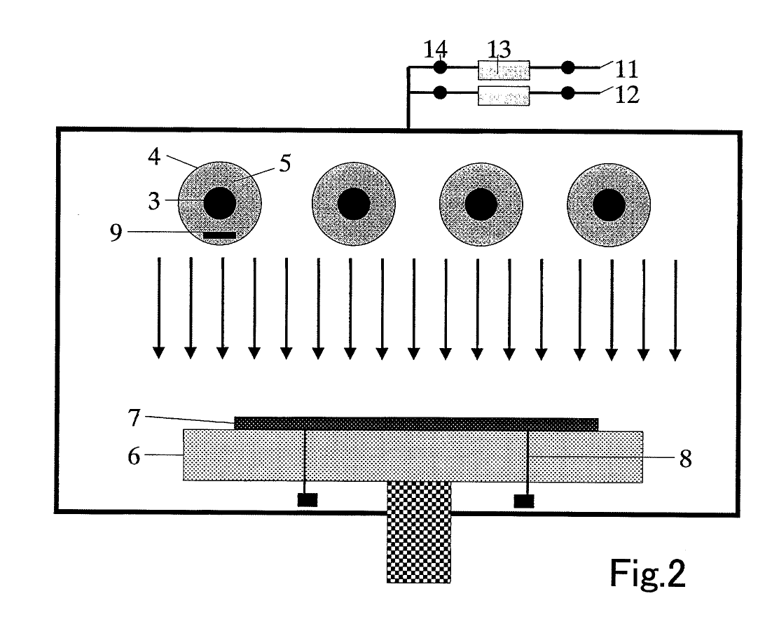

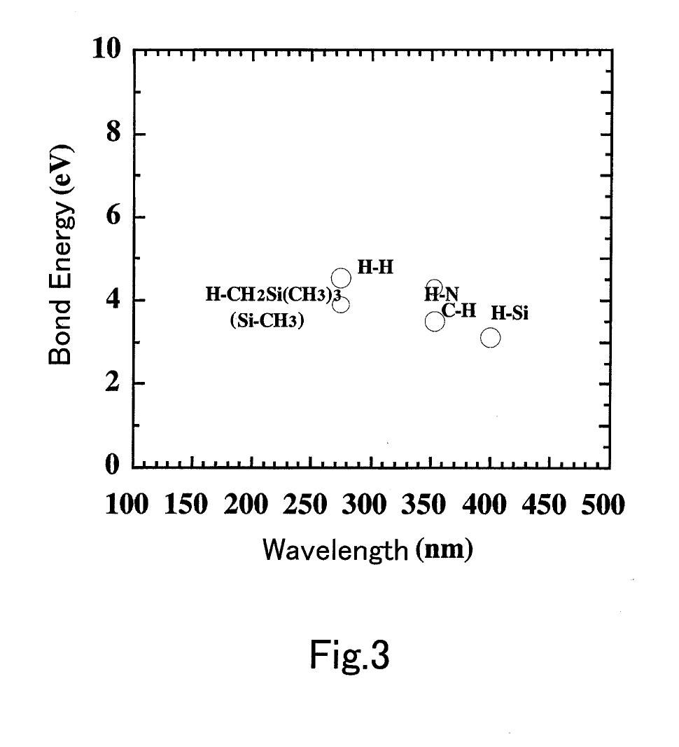

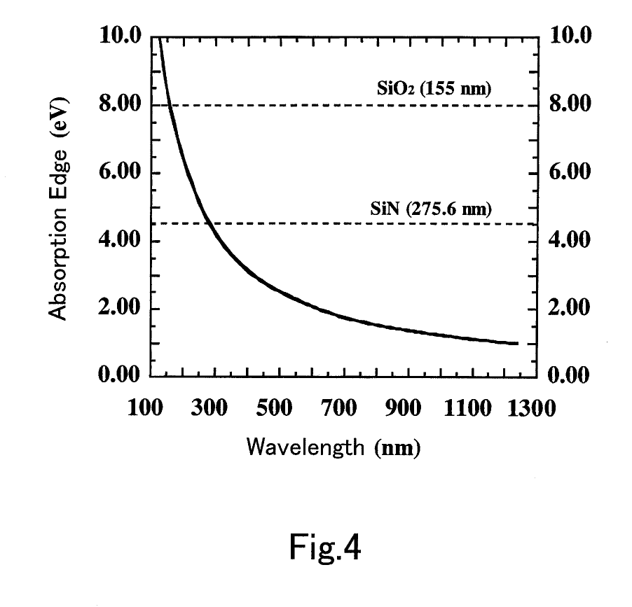

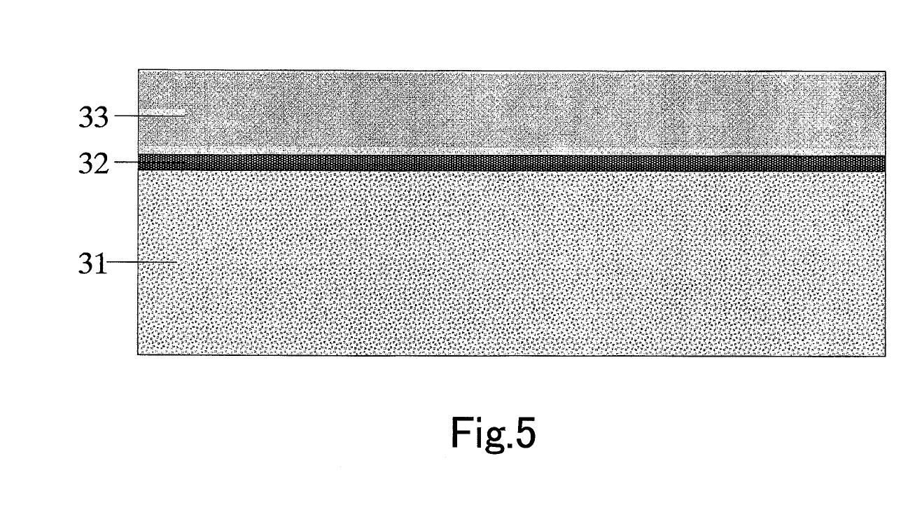

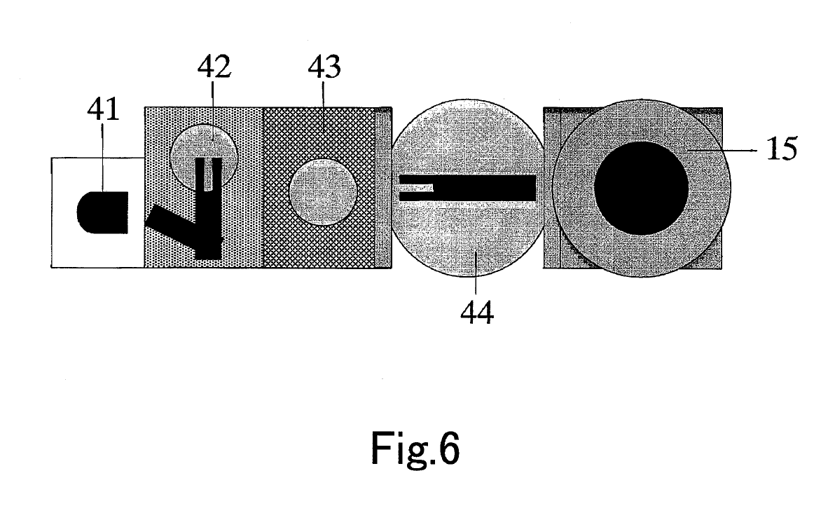

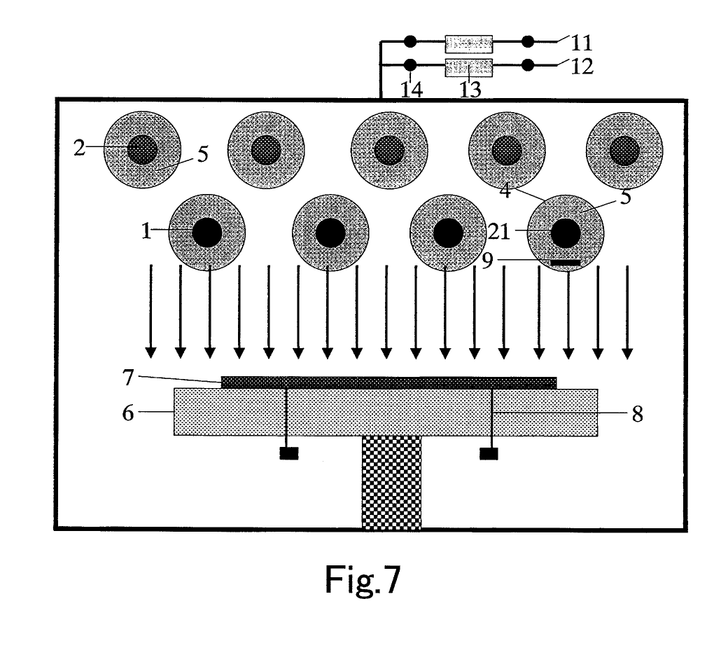

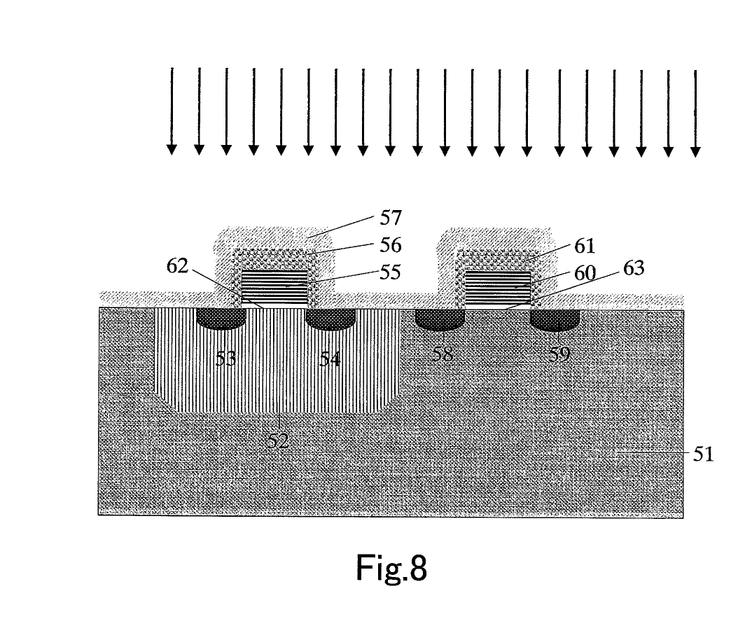

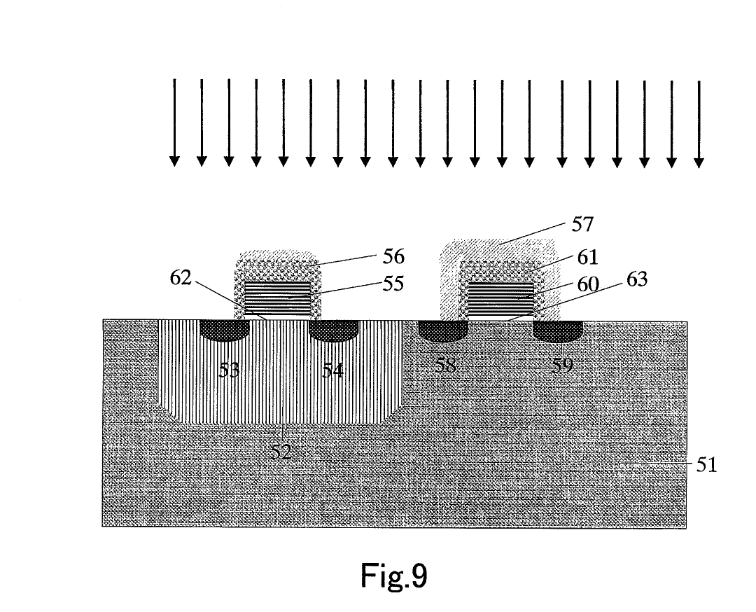

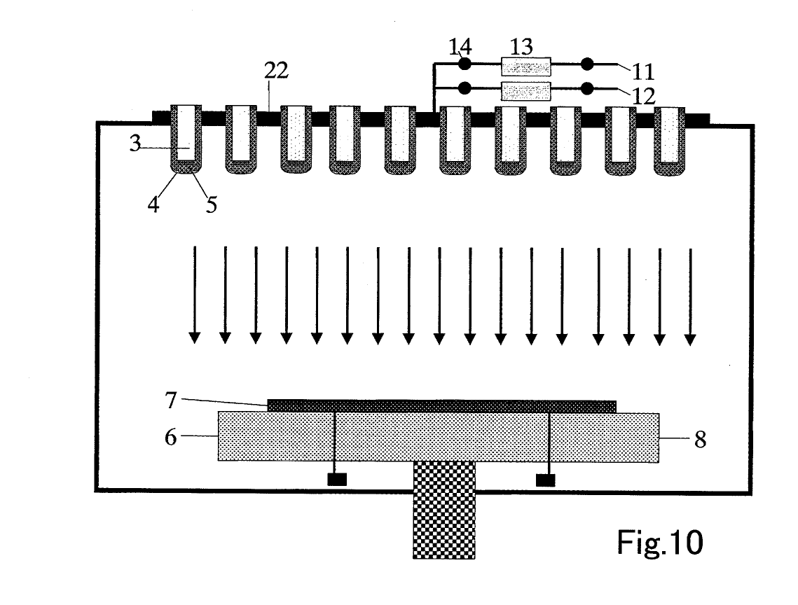

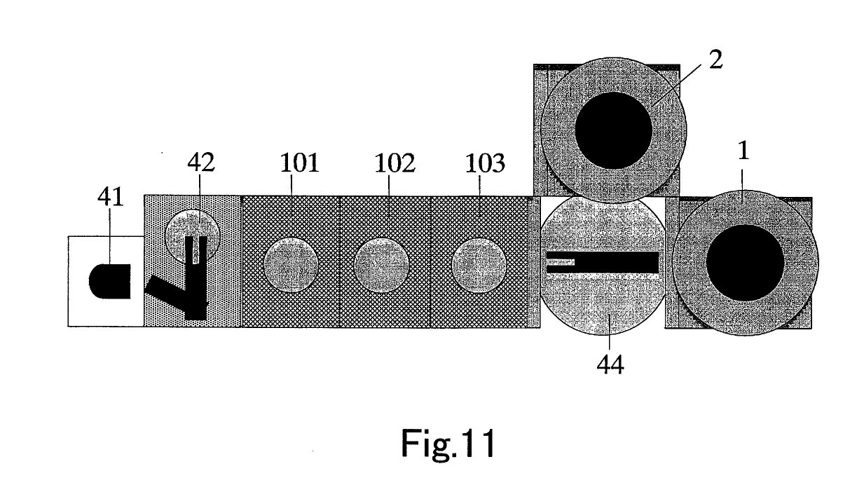

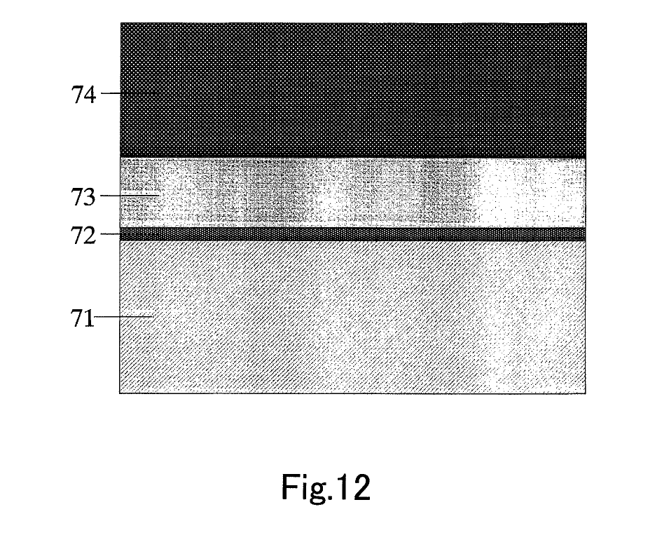

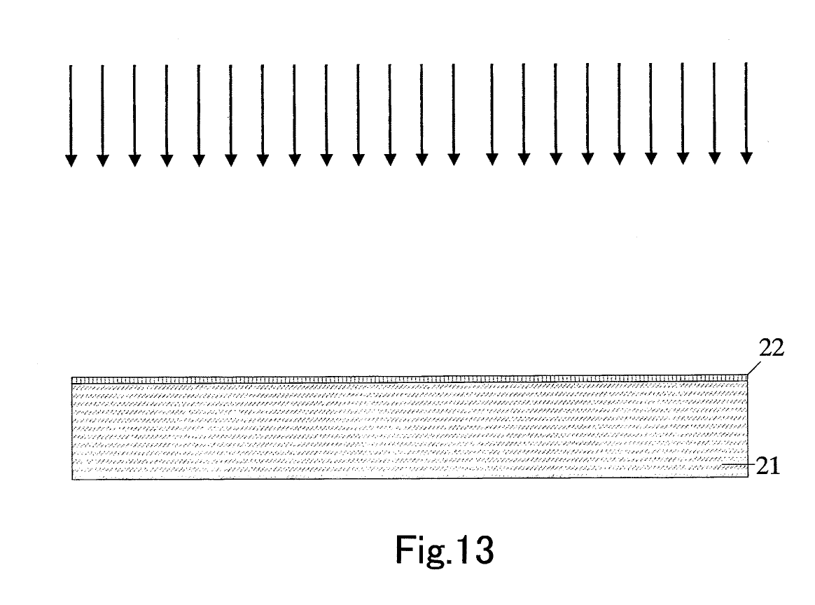

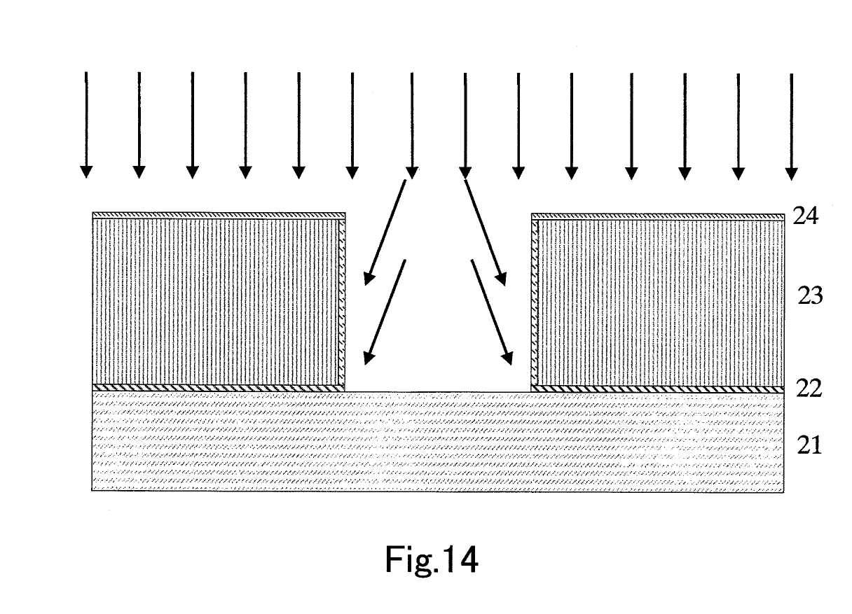

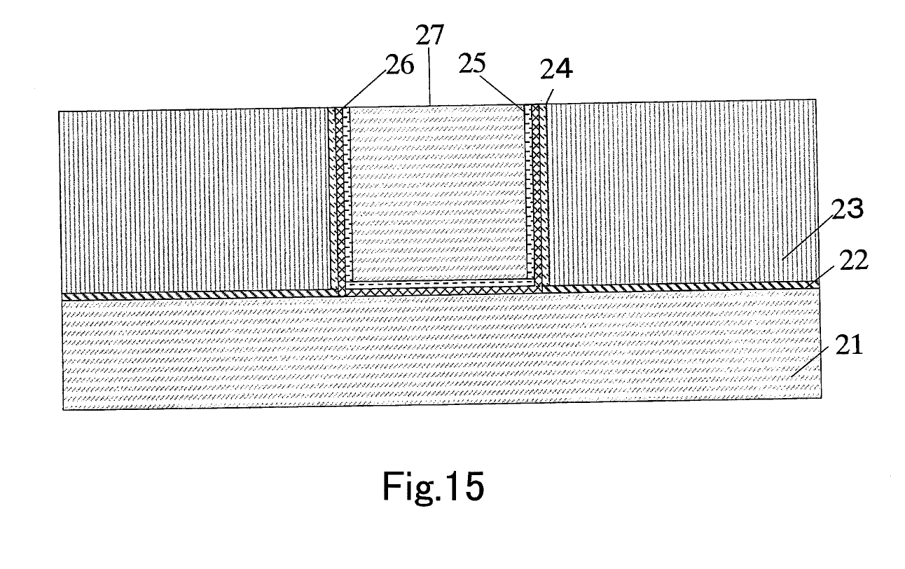

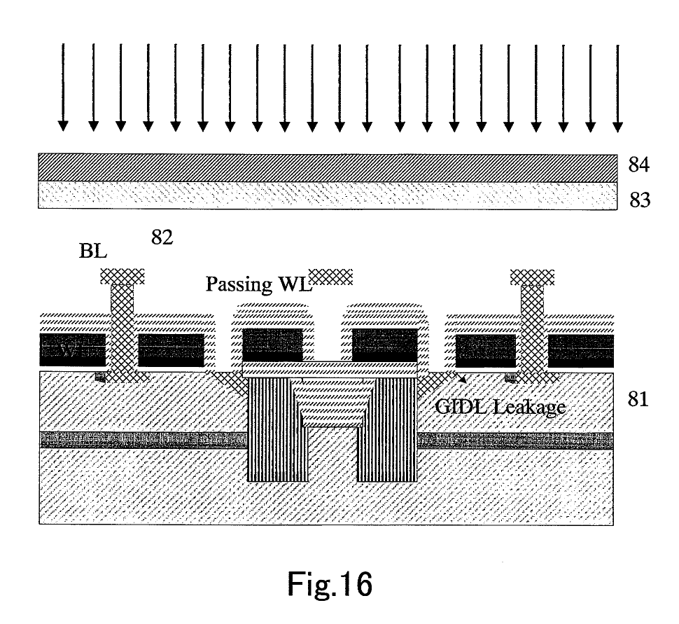

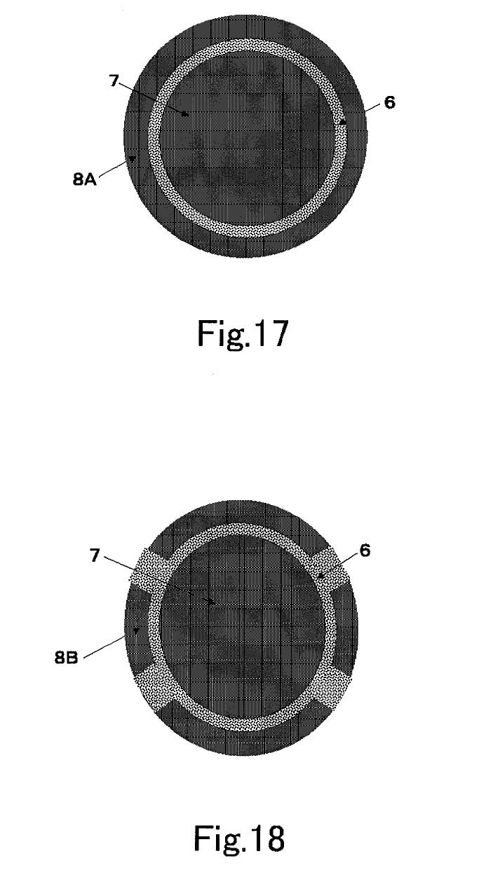

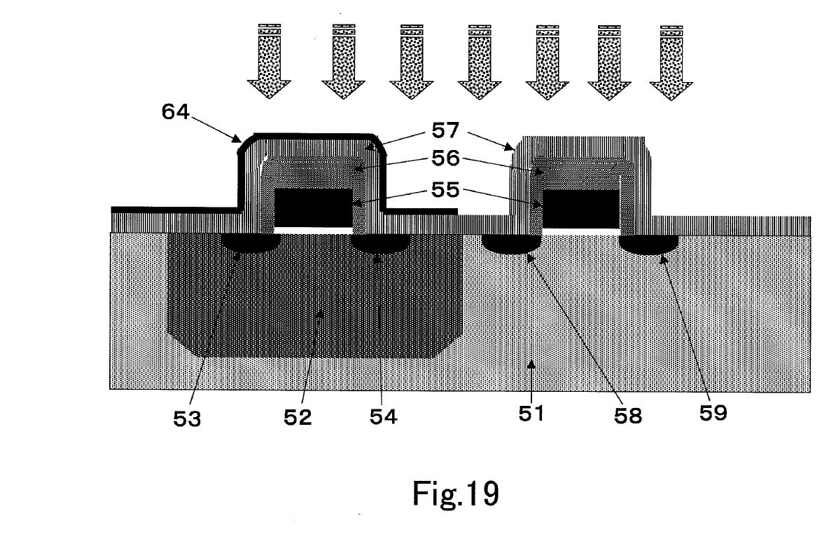

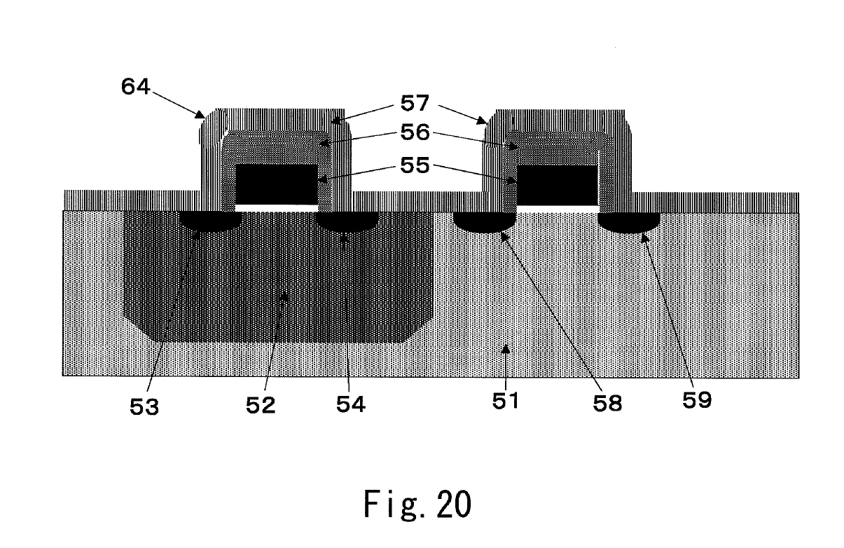

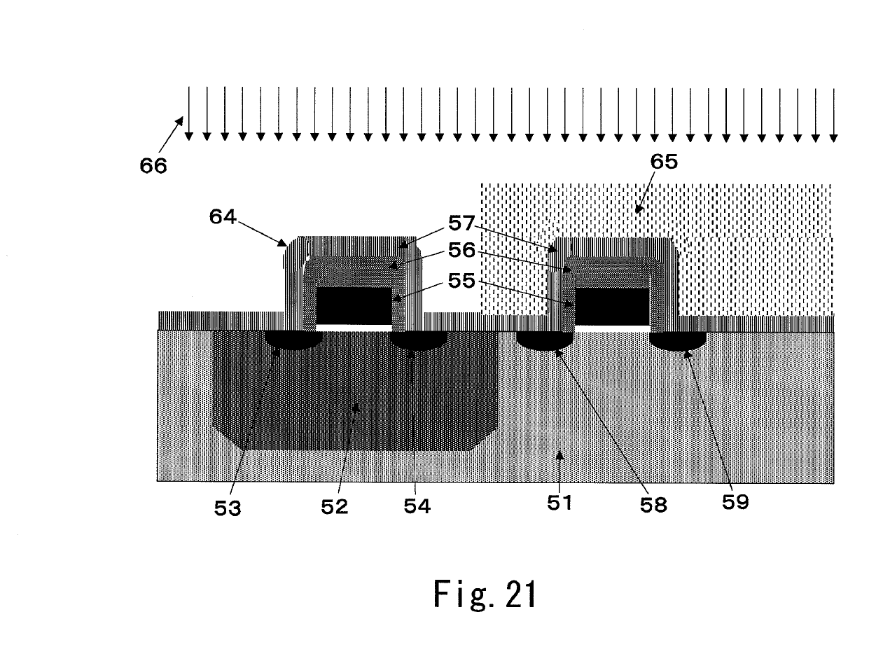

### EXPLANATION OF REFERENCE NUMERALS

1: first chamber
2: second chamber
3: lamp
4: silica pipe
5: inert gas
6: heater
7: wafer
8: pin
9: light receiving sensor
11: piping
12: piping
13: mass flow
14: valve
41: hoop
42: wafer alignment
43: load lock chamber
44: transfer chamber

1. A semiconductor manufacturing apparatus comprising
irradiating means for irradiating light with a wavelength longer than one corresponding to the absorption edge of said insulation film for insulation film and shorter than one necessary for cutting chemical bonds relating to hydrogen of said insulation film,
a heater for applying heat to a wafer comprising the insulation film,
a reaction chamber comprising prevention-removal means for preventing displacement of said wafer for said heater based on static electricity produced between the wafer and the heater by irradiating light from the irradiating means and
means for creating nitrogen atmosphere or inert atmosphere in the reaction chamber when irradiating light.

2. A semiconductor manufacturing apparatus according to claim 1 wherein the insulation film is SiOCH film and the irradiating means irradiates light with a wavelength of 156˜500 nm.

3. A semiconductor manufacturing apparatus according to claim 1 wherein the insulation film is SiOCNH film and the irradiating means irradiates light with a wavelength of 180˜500 nm.

4. A semiconductor manufacturing apparatus according to claim 1 wherein the insulation film is SiCH film or SiC NH film and the irradiating means irradiates light with a wavelength of 180˜500 nm.

5. A semiconductor manufacturing apparatus according to claim 1 wherein the insulation film is SiN film and the irradiating means irradiates light with a wavelength of 240˜500 nm.

6. A semiconductor manufacturing apparatus further comprising carrier device for carrying the wafer comprising the insulation film.

7. A semiconductor manufacturing method comprising
irradiating process for irradiating light with a wavelength longer than one corresponding to the absorption edge of said insulation film for insulation film and shorter than one necessary for cutting chemical bonds to which hydrogen of said insulation film is related,
process for putting the insulation film in nitrogen atmosphere or inert atmosphere when irradiating light,
process for applying heat to the wafer comprising the insulation film when irradiating light and process for preventing displacement of said wafer for said heater based on static
electricity produced between the wafer and the heater.

8. A semiconductor manufacturing apparatus comprising
a first irradiating means for irradiating ultra-violet light with a first wavelength to insulation film, and
a second irradiating means for irradiating ultra-violet light or visible light whose wavelength is different from the first wavelength to the insulation film.

9. A semiconductor manufacturing apparatus according to claim 8 wherein
the insulation film is a film with low dielectric constant,
one of the lights has a wavelength shorter than one necessary for cutting chemical bonds which are not under a stable state in the insulation film, and
another light has wavelength longer than an absorption edge.

10. A semiconductor manufacturing apparatus according to claim 8 wherein
the insulation film is an interlayer insulation film or a barrier insulation film,
one of the lights has a wavelength shorter than one necessary for cutting chemical bonds which are not under a stable state in the insulation film, and
another light has wavelength longer than an absorption edge.

11. A semiconductor manufacturing apparatus according to claim 8 wherein
the insulation film is a gate insulation film with high dielectric constant,
one of the lights has a wavelength necessary for oxidizing transition metal or a wavelength shorter than one necessary for cutting C—H bonds, and
another light has wavelength longer than an absorption edge.

12. A semiconductor manufacturing apparatus comprising
the illumination apparatus according to any one claimed in claim 8-11, and
carrying apparatus for carrying wafers with the insulation film.

13. A semiconductor manufacturing apparatus according to claim 12 wherein the first and second illumination means are arranged in the same or different chamber.

14. A semiconductor device manufactured by a chemical vapor deposition apparatus wherein an insulation film has a dielectric constant equal to and less than 2.4, and Young's modulus more than 5 GPa.

15. A semiconductor device manufactured by a spin coater wherein an insulation film has a dielectric constant equal to and less than 2.3, and Young's modulus more than 6 GPa.

16. An irradiating method comprising
a first irradiating process for irradiating ultra-violet light with a first wavelength to insulation film, and
a second irradiating process for irradiating ultra-violet light or visible light whose wavelength is different from the first wavelength to the insulation film after the first irradiating process.
